(19) United States
(12) Patent Application Publication
(10) Pub. No.: US 2011/0214103 A1
(43) Pub. Date: Sep. 1, 2011

(54) ELECTRICAL CIRCUIT ARRANGEMENT AND METHOD FOR DESIGNING AN ELECTRICAL CIRCUIT ARRANGEMENT

(75) Inventor: Cristian Nicolae Onete, Eindhoven (NL)

(73) Assignee: NXP B.V., Eindhoven (NL)

(21) Appl. No.: 13/127,122

(22) PCT Filed: Nov. 5, 2009
(86) PCT No.: PCT/IB2009/054918

§ 371 Date: May 2, 2011

(30) Foreign Application Priority Data
Nov. 5, 2008 (EP) 08168336.9

(51) Int. Cl. G06F 17/50; H03K 19/00

(52) U.S. Cl. 716/137; 326/37

(57) ABSTRACT

The invention relates to an electrical circuit arrangement comprising a plurality of reconfigurable circuit cells, each reconfigurable circuit cell comprising —a plurality of nodes, —a plurality of links connectable to the nodes, —at least one circuit element, wherein the reconfigurable circuit cells are each configured to form either a node or a link of the electrical circuit arrangement. Furthermore the invention relates to a method for designing an electrical circuit arrangement

### FIELD OF THE INVENTION

The invention relates to an electrical circuit arrangement and method for designing an electrical circuit arrangement. More particularly, the invention relates to electrical circuit arrangements that are designed using the concept of evolvable hardware (EHW).

### BACKGROUND OF THE INVENTION

Evolvable hardware is a relatively new field of research in electronic circuits. It relates to the use of evolutionary algorithms (EA) to create electronics and brings together reconfigurable hardware, artificial intelligence, fault tolerance and autonomous systems. Evolvable hardware further refers to hardware that can change its architecture and behavior dynamically and autonomously by interacting with its environment.

Evolvable hardware has a strong analogy in biology since it also comprises elementary cells, sometimes called chromosomes, the chromosomes being usually controlled by digital signals, which are usually called genotype, which could be seen as a digital control vector. As mentioned above, the evolution process is an evolutionary algorithm, which is usually implemented by using a genetic algorithm (GA), genetic programming (GP) or evolutionary programming (EP) (Jim Torresen, An Evolvable Hardware Tutorial., Proc. of the 14th International Conference on Field Programmable Logic and Applications (FPL'2004), August 2004, Antwerp—Belgium).

The evolution “per se” is an adaptation process of the circuit with the purpose of achieving an objective, which can be a specific electrical function or, in general, a specific behavior.

The most basic part of an EHW is a set of elementary blocks, usually called cells. The cells may be different or they could be of a same type. In any case, a clear distinction between the cells and their inter-connections is made in order to better distinguish between input/output i.e. flow variables and control variables, which normally control the topology of the circuit.

Elementary cells can be analog or digital, and may be simple, such as digital gates, or complex, such as signal generators, multipliers, adders, etc. or complex area of transistors (A. Stoica et al. “Reconfigurable VLSI Architectures for Evolvable Hardware: from Experimental Field Programmable Transistor Arrays to Evolution-Oriented Chips”, IEEE Transactions on VLSI Systems, Special Issue on Reconfigurable and Adaptive VLSI Systems, 9(1): 227-232, February 2001).

### SUMMARY OF THE INVENTION

It is an object of the present invention to provide an electrical circuit arrangement based on the evolvable hardware approach which allows for a reduction of the circuit complexity resulting in easy programming and simple implementation.

The invention is defined by the independent claims. Dependent claims define advantageous implementations.

According to the invention there is provided an electrical circuit arrangement comprising a plurality of reconfigurable circuit cells, each reconfigurable circuit cell comprising a plurality of nodes, a plurality of links connectable to the nodes and at least one circuit element, wherein the reconfigurable circuit cells are each configured to form either a node or a link of the electrical circuit arrangement.

According to the invention the electrical circuit arrangement comprises a plurality of reconfigurable cells. In turn, each reconfigurable circuit cell each comprises a plurality of nodes, a plurality of links connectable to the nodes, and at least one circuit element. In the present invention reconfigurability refers to the property of an electrical circuit, presently of each reconfigurable cell, to connect different circuit elements comprised in the electrical circuit or cell, respectively, to a set of nodes.

According to invention the links are connectable to the nodes. Thus, the links are not necessarily connected to the nodes. In turn, this may imply that there is a switch between each of the links and the respective node the link is connectable to.

What is more, the reconfigurable circuit cells are each configured to form either a node or a link of the electrical circuit arrangement. In this concept every individual cell has a very simple structure comprising nodes, links, which may be simple wires, and at least one circuit element. Therefore, the cells are easy to implement and are each able to perform simple operations but like in the case of a biological organism a group of such cells is capable of performing complex operations.

According to an embodiment each node is connectable to any other node of the cell via a link or the at least one circuit element. This provides for a maximum degree of versatility for each reconfigurable circuit cell resulting in the capability of the electrical circuit arrangement to implement a particularly large variety of functionalities.

Furthermore, each reconfigurable circuit cell may be representable by a planar graph, i.e. they may be implemented on a planar surface as a layer in an integrated circuit. However, it should be pointed out here that in a System in a Package integrated circuit, this restriction is no longer necessary as different cells may be implemented on different chips. A circuit cell that is representable by a planar graph has the advantage that every individual circuit cell and thus the entire circuit arrangement can readily be implemented on a chip.

According to the invention each reconfigurable circuit cell comprises at least one circuit element. The at least one circuit element may be a passive or an active circuit element.

In case of a passive circuit element the at least one circuit element may be a passive lumped bi-terminal device such as a resistor, a capacitor, an inductor etc. A reconfigurable circuit cell that exclusively comprises one or more passive circuit elements is referred to as a passive circuit cell. Using simple passive circuit elements in the circuit cells has the advantage of determining cost- and energy-efficient components. It is to be noted that a passive circuit cell may also comprise an active circuit element which is deactivated.

According to a further embodiment at least one reconfigurable circuit cell of said plurality of reconfigurable circuit cells may be a passive cell having at least one passive circuit element. Electric circuit elements that are composed of passive circuit cells may operate as synthesizing filters, equalizers, or adaptation circuits. Furthermore, passive circuit cells may operate as input cells in an electric circuit arrangement having a plurality of circuit cells of both passive and active circuit cells. Recall that a simple connection or wire is also a passive device in the context of the present invention.

Additionally to passive circuit cells, active circuit cells allow the implementation of a larger diversity of circuits. Active circuit cells comprise at least one active circuit element wherein the at least one circuit element may be a device which uses an external supply source in order to work properly. Active circuit elements may thus be controlled sources, negative impedances, gyrators, immitance converters etc.

The active circuit element may have at least three terminals. In particular, the active circuit element may be a quadripole device such as an operational amplifier, a transconductance amplifier, a transimpedance amplifier or a controlled source which may be made up of a cascade connection of either of a transconductance amplifier coupled to a transimpedance amplifier or the other way around, respectively. The cell itself may comprise only active devices as e.g. CMOS transistors, the approach being very useful in the design of digital circuits and certain type of linear circuits. However, this does not exclude the possibility to include an active device in a passive cell and then to consider this combination as a new cell. According to an embodiment at least one reconfigurable circuit cell of said plurality of reconfigurable circuit cells is an active cell having at least one active circuit element.

According to a further embodiment of the invention the electrical circuit arrangement may have a first plurality of passive cells said passive cells each forming a hyper link of the circuit arrangement and a second plurality of active cells each forming a hyper node of the electrical circuit arrangement. In particular, the electrical circuit arrangement may be a CMOS circuit having a first plurality of passive cells said passive cells each having a passive circuit element in the form of a conductor and a second plurality of active cells each forming a MOS transistor. The CMOS circuit may be a digital or an analog circuit. Alternatively, the electrical circuit arrangement may have a first plurality of passive cells said passive cells each forming a hyper node of the circuit arrangement and a second plurality of active cells each forming a hyper link of the electrical circuit arrangement.

According to a further embodiment of the invention the plurality of circuit cells comprised in the electrical circuit arrangement may form at least one equalizer subcircuit and at least one gain subcircuit, wherein the equalizer subcircuit is coupled to a gain subcircuit. Since analog circuits generally may be partitioned in two parts, a frequency equalization part and a gain part this feature particularly enhances the variability in designing analog circuit arrangements on the basis of a plurality of reconfigurable circuit cells.

Furthermore, a reconfigurable circuit may be configured by a set of data. In addition, the reconfigurable circuit cell may comprise both active and passive circuit elements and thus an active and a passive part. Both parts, i.e. the active and the passive part, may be configured in this case by a separate set of data which may be referred to as a “genome”.

What is more, the set of data may comprise a first subset of data for controlling the connectivity between the links and nodes of the reconfigurable circuit cell. In case the reconfigurable circuit cell comprises both an active and a passive part the first subset of data may be further subdivided so as to allocate individual units of data, e.g. individual bits, to the active and the passive part of the circuit cell.

According to another embodiment the set of data may comprise a second subset of data for bypassing the cell. The second subset of data may thus indicate whether the respective reconfigurable circuit cell is activated or bypassed in the electrical circuit arrangement.

According to a further embodiment the set of data comprises a third subset of data for indicating the type of the at least one circuit element. Therefore, the third subset of date may for example indicate whether the cell is used purely as an active cell, i.e. without passive components, to indicate whether the cell is used purely as a passive cell, i.e. either comprising only admittances or simple connections, or finally to indicate that the cell is used universally i.e. comprising an active part and a passive part.

Furthermore, the set of data comprises a fourth subset of data for indicating the type and value of the at least one circuit element. The fourth subset of date may be implemented as a set of pointers so as to indicate the type and the values of a passive circuit element, to show the type and the values of an active circuit element used, e.g. a controlled source, and to indicate its model in a specific implementation. The pointers may address a database comprising the above-mentioned features.

According to another aspect of the invention a method for designing an electrical circuit arrangement is disclosed, wherein a plurality of reconfigurable circuit cells is provided, each reconfigurable circuit cell comprising a plurality of nodes, a plurality of links connectable to the nodes and at least one circuit element, wherein each reconfigurable circuit cell is configured by a set of data, the method comprising the steps of setting up the circuit arrangement by successively connecting the reconfigurable circuit cells of said plurality of reconfigurable circuit cells, wherein a first connected reconfigurable circuit cell determines the set of data of the next reconfigurable circuit cell to be connected.

These and other aspects of the present patent application become apparent from and will be elucidated with reference to the following figures. The features of the present application and of its exemplary embodiments as presented above are understood to be disclosed also in all possible combinations with each other.

### BRIEF DESCRIPTION OF THE DRAWINGS

In the Figures show:

FIGS. 1a, b two reconfigurable circuit cells each represented by a planar graph;

FIG. 2 a first reconfigurable indefinite admittance matrix (RIAM) of a reconfigurable circuit cell;

FIG. 3 the connection between two nodes within a reconfigurable circuit cell;

FIG. 4 a second indefinite reconfigurable admittance matrix (RIAM) of a reconfigurable circuit cell;

FIG. 5 a first electrical circuit arrangement comprising a plurality of reconfigurable circuit cells;

FIG. 6 a second electrical circuit arrangement comprising a plurality of reconfigurable circuit cells;

FIG. 7 a third electrical circuit arrangement comprising a plurality of reconfigurable circuit cells;

FIG. 8 a reconfigurable circuit cell comprising active circuit elements;

FIG. 9 a reconfigurable circuit cell comprising both active and passive circuit elements;

FIG. 10 a circuit arrangement comprising an equalizer subcircuit coupled to a gain subcircuit;

FIG. 11 a fourth electrical circuit arrangement comprising a plurality of reconfigurable circuit cells;

FIG. 12 a fifth electrical circuit arrangement comprising a plurality of reconfigurable circuit cells; and

FIG. 13 a sixth electrical circuit arrangement comprising a plurality of reconfigurable circuit cells;

### DETAILED DESCRIPTION OF THE DRAWINGS

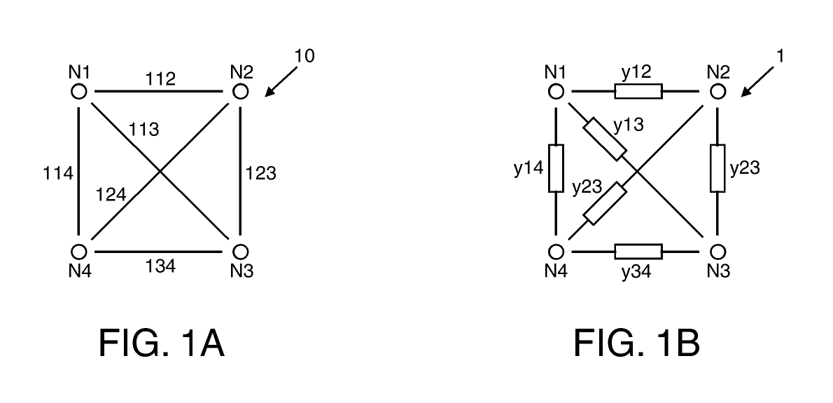

FIG. 1a shows a reconfigurable circuit cell 10. The circuit cell 10 of FIG. 1a comprises four nodes N₁, N₂, N₃, N₄ and six links I₁₂, I₂₃, I₃₄, I₁₄, I₁₃, I₂₄. As can be seen from FIG. 1a, a connection between each individual node N₁, N₂, N₃, N₄ and the three remaining nodes of the reconfigurable circuit cell 10 can be established. As further shown in FIG. 1a, the links I₁₂, I₂₃, I₃₄, I₁₄, I₁₃, I₂₄ are actually not connected to the nodes N₁, N₂, N₃, N₄ but are connectable to the nodes N₁, N₂, N₃, N₄. The actual connection between one link I₁₂, I₂₃, I₃₄, I₁₄, I₁₃, I₂₄ and one node N₁, N₂, N₃, N₄ may be implemented by way of a switch (not shown in detail).

The reconfigurable circuit cell 10 shown in FIG. 1a comprises pure links, e.g. simple “wires”, which may be referred to as passive circuit elements having a very low impedance or a very high admittance, respectively.

FIG. 1b shows a reconfigurable circuit cell 1 in which each link comprises a passive circuit element y₁₂, y₂₃, y₃₄, y₁₄, y₁₃, y₂₃. By way of example the circuit elements yᵢⱼ may be linear passive two terminal lumped devices such as capacitors, resistors, inductors etc., however transformers are not excluded, too.

Both circuit cells 10, 1 shown in FIG. 1a and FIG. 1b are represented by planar graphs thus allowing a direct implementation on a chip.

A circuit as shown in FIG. 1b may be described using an equi-cofactor matrix such as the Indefinite Admittance Matrix (IAM).

Regardless of what type of circuit elements yᵢⱼ are integrated into the links in the circuit cell 1 of FIG. 1b the circuit cell 1 may be described by the Incidence Matrix (IM), which is a matrix having n rows and 1 columns, i.e. it has an n×1 dimension, wherein n represents the number of nodes and 1 is the number of links of the circuit cell. If a circuit element yᵢⱼ is connected between nodes i and j and the link is labeled as k-link kε[1, . . . , 1] then in the IM, the elements (i, k) and (j, k) are set to 1 and the rest of the elements of the column k are set to 0. It may further be associated to any link a direction of a current flowing through it such that, by way of example, a positive sign is assigned to a link having a current leaving a node and a negative sign is assigned to a link having a current entering a node. What is obtained when these equations are graphically represented is a directed graph or di-graph. Hence, an IM having its terms equal to +1, −1 or 0 characterizes a di-graph.

In the case of the passive circuit cell 1 shown in FIG. 1b, i.e. a circuit cell comprising exclusively passive circuit elements, the IAM is a symmetric matrix, i.e. yᵢⱼ=yⱼᵢ for ∀i,j with i≠j. Furthermore.

$${y}_{ii} = {\sum }_{{j = 1}_{i \neq j}}^{N} {y}_{ij} .$$

The circuit cell 1 of FIG. 1 b comprises six circuit elements yᵢⱼ. In general, a circuit having N nodes, each node being connected to all the other nodes could be represented as a complete graph and there are N(N−1)/2 distinct admittances for the circuit having N nodes and passive linear bi-terminal devices.

It can be shown that any circuit comprising passive lumped linear bi-terminal devices has an IAM given by the following relation:

IAM=INCM*P*DIAG1*P^{T}*INCM^{T} (1)

wherein INCM is a suitably chosen incidence matrix and

$$DIAG = [ \begin{matrix}{y}_{12} & 0 & 0 & 0 & 0 & 0 \\ 0 & {y}_{13} & 0 & 0 & 0 & 0 \\ 0 & 0 & {y}_{14} & 0 & 0 & 0 \\ 0 & 0 & 0 & {y}_{23} & 0 & 0 \\ 0 & 0 & 0 & 0 & {y}_{24} & 0 \\ 0 & 0 & 0 & 0 & 0 & {y}_{34}\end{matrix} ] \qquad ( 2 )$$

In case of the circuit cell 1 shown in FIG. 1b its INCM is given by the equation (3).

$$INCM = [ \begin{matrix}1 & - 1 & - 1 & 0 & 0 & 0 \\ - 1 & 0 & 0 & 1 & - 1 & 0 \\ 0 & 1 & 0 & - 1 & 0 & - 1 \\ 0 & 0 & 1 & 0 & 1 & 1\end{matrix} ] \qquad ( 3 )$$

Applying equation (1) it can be found that IAM should be as shown in equation (4), which is the IAM of the circuit that can be obtained by inspection, i.e. it is easily derivable by looking at the circuit.

$$IAM = [ \begin{matrix}{y}_{12} + {y}_{13} + {y}_{14} & - {y}_{12} & - {y}_{13} & - {y}_{14} \\ - {y}_{12} & {y}_{23} + {y}_{24} + {y}_{12 } & - {y}_{23} & - {y}_{24} \\ - {y}_{13} & - {y}_{23} & {y}_{34} + {y}_{13} + {y}_{23} & - {y}_{34} \\ - {y}_{14} & - {y}_{24} & - {y}_{34} & {y}_{14} + {y}_{24} + {y}_{34}\end{matrix} ] \qquad ( 4 )$$

If a different DIAG matrix, e.g. DIAG1, is chosen the admittances appear in a different order in the IAM. However, it is well known from the art that there is a permutation matrix P such that equation (5) holds:

DIAG=P*DIAG1*P^{T} (5)

Hence, no matter how the diagonal matrix is actually chosen, according to equation (5) there will always exist a permutation matrix, which makes relation (1) hold. In general, equation (1) can be obtained by direct calculus.

A passive circuit comprising only lumped passive bi-terminal devices, i.e. each link is characterized by one admittance as in the case of the circuit cell 1 shown in FIG. 1b, can be described by a DIAG matrix of dimension 1×1.

The representation of IAM as shown in equation (1) has a further advantage because it requires low memory resources. It requires only vectors (lists) of the diagonal matrix and the lists corresponding to the rows of the INCM matrix.

A circuit cell may be described by the indefinite admittance matrix IAM. However, in certain cases it is more useful to describe the circuit cell using an impedance approach. Usually, if the graph is planar, a dual graph would describe such a circuit. Even more, an indefinite impedance matrix description is also available in the art.

Now referring to reconfigurability, the following definition can be provided:

A Reconfigurable Admittance Matrix (RAM) is obtained using equation (6)

RAM=RINCM*DIAG*RINCM^{T} (6)

in which DIAG can be as shown in equation (5) and RINCM is a reconfigurable incidence matrix which is described below.

If equation (6) is applied to a complete graph having 4 nodes as shown in FIG. 1b its RINCM is given by equation (7), and the diagonal matrix is given by the equation (4).

$$RINCM = [ \begin{matrix}{w}_{11} & - {w}_{12} & - {w}_{13} & 0 & 0 & 0 \\ - {w}_{21} & 0 & 0 & {w}_{24} & - {w}_{25} & 0 \\ 0 & {w}_{32} & 0 & - {w}_{34} & 0 & - {w}_{36} \\ 0 & 0 & {w}_{43} & 0 & {w}_{45} & {w}_{46}\end{matrix} ] \qquad ( 7 )$$

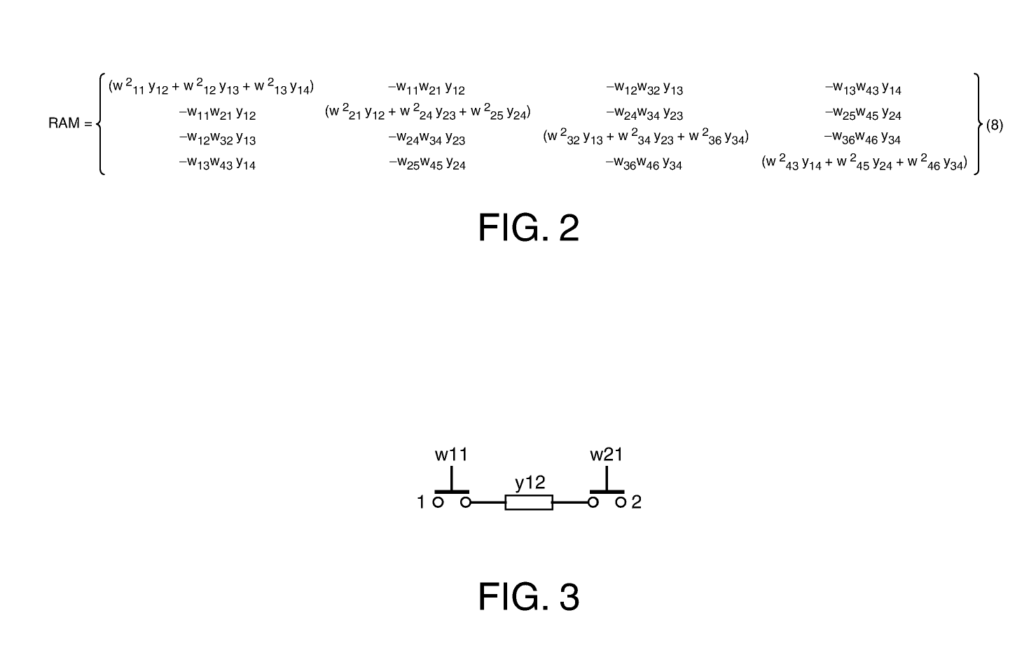

Applying equation (6) it can finally be found that the RAM has the form shown in equation (8) of FIG. 2.

The reconfigurable admittance matrix of equation (8) of FIG. 2 is a Reconfigurable Indefinite Admittance Matrix (RIAM) if and only if the sum of all elements on any line and on any column is zero, according to the definition of the IAM. Hence, for the matrix of equation (8) of FIG. 2 the following system of equations must be fulfilled:

w₁₁(w₁₁−w₂₁)y₁₂+w₁₂(w₁₂−w₃₂)y₁₃+w₁₃(w₁₃−w₄₃)y₁₄=0

w₂₁(w₂₁−w₁₁)y₁₂+w₂₄(w₂₄−w₃₄)y₂₃+w₂₅(w₂₅−w₄₅)y₂₄=0

w₃₂(w₃₂−w₁₂)y₁₃+w₃₄(w₃₄−w₂₄)y₂₃+w₃₆(w₃₆−w₄₆)y₃₄=0

w₄₃(w₄₃−w₁₃)y₁₄+w₄₅(w₄₅−w₂₅)y₂₄+w₄₆(w₄₆−w₃₆)y₃₄=0 (9)

FIG. 3 depicts the connection between node 1 and node 2 within a reconfigurable circuit cell, which characterizes any connection between any two nodes. For graphical purposes, fictitious nodes have been added at each end of the admittance y₁₂. The following situations may be encountered:

Situation 1. Both variables w₁₁ and w₂₁ are in logical ONE state and therefore the switches are ON. In this situation, the admittance is physically connected between nodes 1 and 2.

Situation 2. Both variables w₁₁ and w₂₁ are in logical ZERO state and therefore the switches are OFF. In this situation, the admittance is disconnected from nodes 1 and 2.

Situation 3. One variable is in logical ONE state and the other is in the ZERO state, corresponding to a situation when only one end of the admittance is connected to a node.

In situations 1 and 2 the system (9) is automatically fulfilled and therefore the matrix of equation (8) of FIG. 2 is a RIAM.

In case w₂₁ is ZERO and w₁₁ is ONE. The first line of the system (9) becomes as shown in equation (10).

y_{1,2}+w_{1,2}(w_{1,2}−w_{3,2})y_{1,3}+w_{1,3}(w_{1,3}−w_{4,3})y_{1,4}=0 (10)

If w₁₂ and w₁₃ are ZERO simultaneously or w₁₂=w₃₂ and w₁₃=w₄₃, then y₁₂ should be ZERO i.e. there is no admittance between nodes 1 and 2. The remaining situation is given by equation (11),

w₁₂=w₁₃=1

w₃₂=w₄₃=0

implying that also the other admittances have an end which is not connected to any node, and equation (10) becomes equation (12).

y₁₂+y₁₃+y₁₄=0 (12)

From equation (12), it results that at least one of the admittances is active, i.e. it is negative. Furthermore, all the admittances of node 1 are connected only to node 1 and disconnected from nodes 3 and 4 of the reconfigurable circuit cell. Following the same reasoning, it results that in any other node there will be a negative admittance and the other admittances are disconnected from the other nodes.

Hence, the circuit cell shown in part in FIG. 3 is transformed in an active one. It is further observed that an admittance having a disconnected end is transformed into a noise generator and therefore this situation should be always be avoided. Any software implementing such a reconfiguration method should either fully connect/disconnect any admittance of the circuit cell.

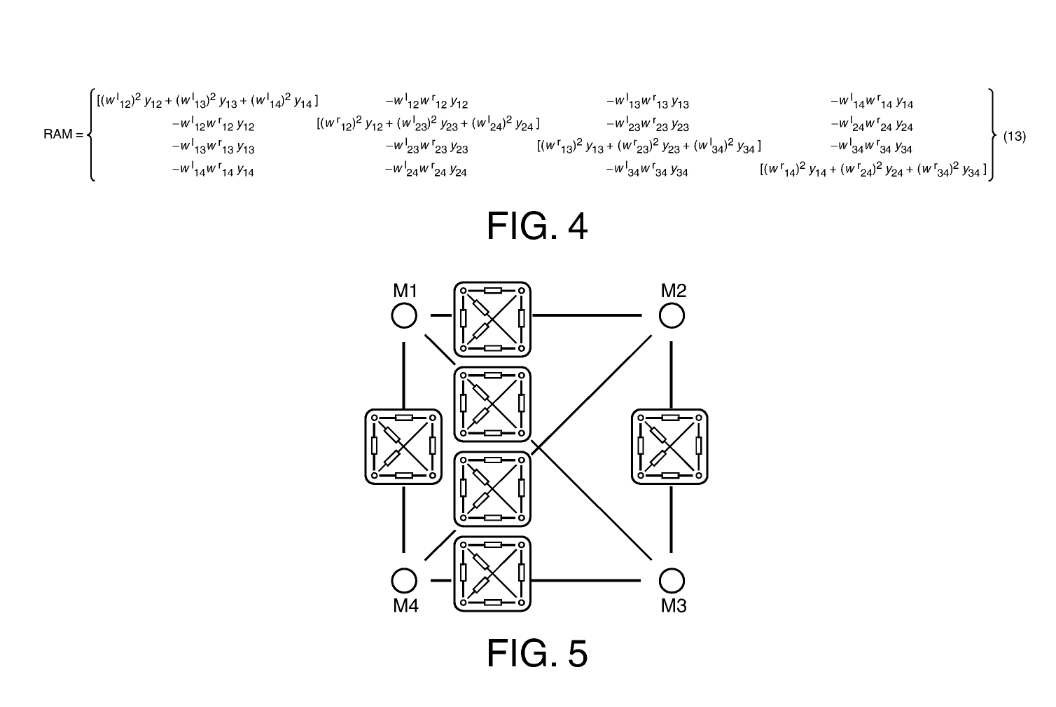

Each connection of an admittance yᵢⱼ is determined by a left connection and a right connection, the connectivity being implemented using a left switch and a right switch, respectively. These switches (not explicitly shown in FIG. 3) are denoted by wᵢⱼ¹ and wᵢⱼ^{r}, respectively. Using these notations, the RAM can be written as shown in relation (13) presented in FIG. 4.

It is easy to see that all the elements of the matrix that are not on the main diagonal are written as a product between the left and right switches and the respective admittance they are attached to. The matrix is symmetric because it describes a passive circuit. As a consequence yᵢⱼ=yⱼᵢ. The elements yᵢⱼ of the matrix are obtained as a sum of terms in the form (wᵢⱼ¹)²yᵢⱼ if i<j and in the form (wᵢⱼ^{r})²yᵢⱼ if i>j.

The matrix shown in equation (13) describes any type of reconfigurable circuit cell comprising passive lumped bi-terminal circuit elements including simple wires. Because of this general interpretation of the admittances, a lot of combinations of admittances are possible, even if we consider a relatively small circuit cell, such as the one shown in FIG. 1b.

In a first example, the circuit cell shown in FIG. 1b is a bi-partite graph i.e. it is obtained from the circuit cell shown in FIG. 1b by assuming that, for example, two nodes are input nodes, which are connectable to two output nodes. In general, a bi-partite graph describes a circuit having m input nodes connectable to n output nodes, no connections existing between either the input nodes or between the output nodes, respectively. Accordingly, the graph may be built using the links between each of the input nodes say (1,2) and the output nodes say (3,4), the links being between the pairs of nodes thus being (1, 3); (1, 4); (2, 3); and (2, 4).

In a second example, a series combination of admittances between nodes, a parallel combination of admittances and a combination of these two are also obtainable. For example, if nodes (1 and 4) and (2 and 3) of the circuit cell of FIG. 1b are connected via wires and nodes (1 and 2) and (3 and 4) are connected via admittances then these admittances are connected in parallel to each other. On the other hand two nodes, e.g. 1 and 2, may be connected via a chain of admittances such as e.g. y₁₄, y₃₄ and y₃₂. In this way, a lot of combinations can be obtained with a relatively simple circuit and therefore a lot of circuit functions can be generated, accordingly.

The circuit shown in FIG. 1b is a passive reconfigurable circuit cell with 4 nodes.

Referring now to the circuit arrangement of FIG. 5 it can easily be recognized that this is a circuit arrangement having a similar topology to that of the circuit cell shown in FIG. 1b with a main difference—the links between the nodes M1, . . . , M4 are implemented as reconfigurable circuit cells having passive circuit elements yᵢⱼ, as shown in FIG. 1b.

As a direct consequence the RIAM of the circuit shown in FIG. 5 is given by equation (14).

RIAM=RINCM*DIAG(Y)*RINCM^{T} (14)

In equation (14), each Y element is described by equation (6) and corresponds to any link between two nodes of the circuit. Algorithmically, first a configuration for each of the Y elements is selected, i.e. an yᵢⱼ element between any pair of nodes Mᵢ and Mⱼ, i=1, . . . , 4, j=1, . . . , 4, i≠j is selected, and then any circuit function using the RIAM given by equation (14) is determined.

In a matrix the cofactor, or the minor, of an element xⱼₖ is defined as the determinant of the matrix obtained from the original one by removing the line j and the line k*(−1)^{j+k}. This cofactor is indicated by Dₖ^{j} and it is called “first order cofactor”.

The above definition may be applied mutatis-mutandis to the already obtained cofactor in relation to another element xⱼ₁ₖ₁. This new cofactor i.e. a second order cofactor will be denoted by Dₖₖ₁^{jj1}. An n order cofactor will be denoted by D_{k1k2 . . . kn}^{j1j2 . . . jn} wherein the lower subscripts refer to rows and the upper subscripts refer to columns. It is already known from the art (S. K. Mitra, “Analysis and Synthesis of Linear Active Networks”, John Wiley & Sons, Inc., 1969) that the main circuit functions may be determined using the IAM and then the RIAM. The results are as shown in equations (15):

$${Z}_{pr}^{ij} = \frac{{V}_{ij}}{{I}_{pr}} = sgn ( p - r ) sgn ( i - j ) \frac{{D}_{ij}^{pr}}{{D}_{n}^{n}} \\ \frac{{V}_{ij}}{{V}_{pr}} = sgn ( p - r ) sgn ( i - j ) \frac{{D}_{ij}^{pr}}{{D}_{mn}^{mn} } \qquad ( 15 )$$

In equations (15), the sign functions i.e. sgn(argument) are +1 if the argument is greater than zero and −1 if the argument is smaller than zero. In the above equations, it is assumed that a current source is applied between the nodes p and r and the impedance between nodes (i, j) and (p, r) has to be determined. The second equation in system (15) shows how to find a voltage transfer function between nodes (i, j) and (p, r). In equations (15) Dₙⁿ refers to the first order cofactor of the IAM and Dᵢⱼ^{pr} refers to a second order cofactor.

The main consequence of the above approach is that the complexity of the calculus needed to analyze the circuit is very much reduced.

Determining any function of a circuit requires determinant calculations of order (n−1) and (n−2), each involving (n−1)³ operations i.e. the algorithms are of complexity O(n³). If the full circuit shown in FIG. 5 is thus considered, then the algorithm for any determinant of the circuit has the complexity O(27³) while by considering the approach above, the complexity is reduced to 7O(3³), which is much less.

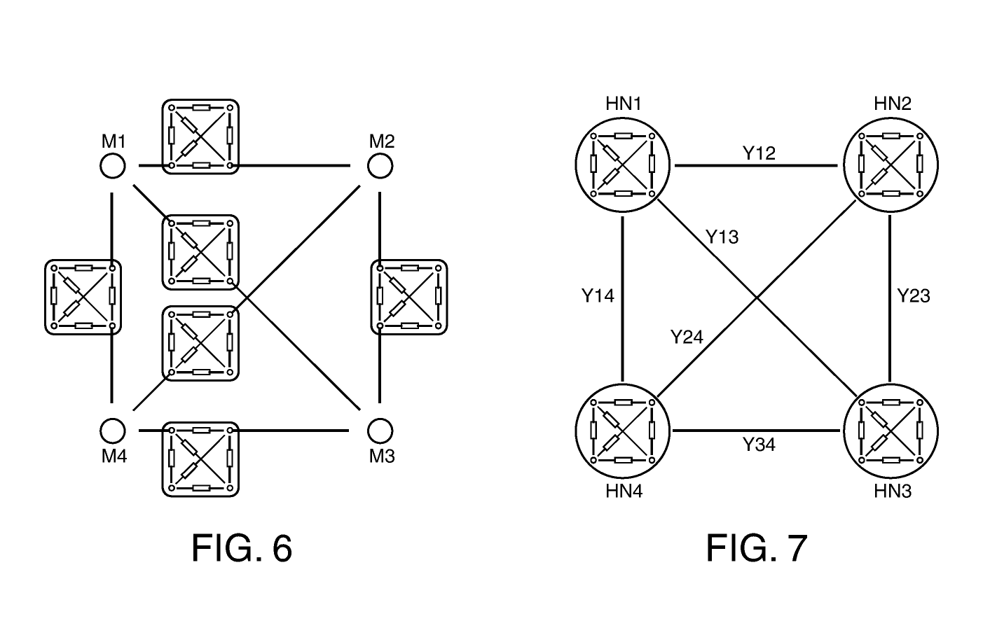

FIG. 6 shows an electrical circuit arrangement in which any node Mᵢ is also a node of any passive reconfigurable circuit cell connected to it. It is observed that the number of connections is reduced and the complexity is in between the approach used above and that of a circuit having only simple connectable links.

FIG. 7 shows an electrical circuit arrangement in which the passive reconfigurable circuit cells, e.g. of FIG. 1b, are considered as any of the nodes M₁, . . . , M₄ of the circuit arrangement, which in turn become hyper nodes HN₁, . . . , HN₄.

Passive reconfigurable circuit cells may be used for synthesizing filters, equalizers, or adaptation circuits, as well as input cells, in an array having a plurality of stem cells.

Additionally to these cells, active cells enrich the possibilities for implementing a larger diversity of circuits.

An active reconfigurable circuit cell contains at least one active circuit element. The active circuit element may use an external supply source in order to work properly. In this category fall for example controlled sources, negative impedances, gyrators, immitance converters, etc.

In the following—without limiting the scope of the present invention—only active circuit elements are considered which have 4 nodes. It is to be noted that most of the active circuit elements mentioned above may be modeled as a quadripole or as a di-port.

Between all possible quadripoles, the controlled sources are amongst the simplest ones. A typical controlled source is the voltage controlled current source, which is the preferred model for any type of transistor. However, even more complex active devices, may be considered, such as Operational Amplifiers, transconductance amplifiers, transimpedance amplifiers, etc. All these devices have the property that they can be depicted as a 4-nodes graph having their links represented by impedances/admittances and controlled or not voltage, or current, sources.

The use of a certain type of controlled source as an active circuit element in a reconfigurable circuit cell is decided by the application itself via its design requests as type of input/output signals, frequency range of operation and by the designer's choices, derived from his own experience and/or from previous knowledge or documentation. Additionally there may be constraints on occupied area in a chip, ease to program etc. Therefore it is expectable to have applications using, in their most general form, any type of controlled source. Hence, in order to have maximum reconfigurability possibilities, it might be useful to have all types of controlled sources implemented.

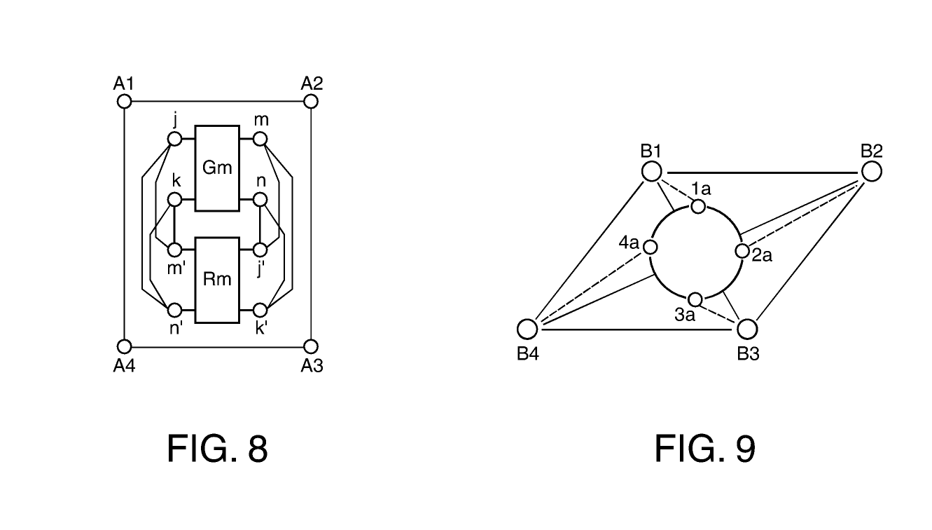

FIG. 8 shows a reconfigurable circuit cell comprising four nodes A₁, A₂, A₃, A₄ and two active circuit elements. More specifically, the reconfigurable circuit cell comprises a transconductance amplifier (GmAmplifier) and a transimpedance amplifier (RmAmplifier).

By using a transconductance amplifier Gm and a transimpedance amplifier Rm all other types of controlled sources may be built using a cascade connection of either of a Gm amplifier coupled to a Rm amplifier or the other way around, respectively. At the same time, in order to have maximum flexibility, it is useful to be able to use any of the individual Rm or Gm amplifier.

As a consequence, each node of any controlled source Rm, Gm should be connectable to any node A₁, A₂, A₃, A₄ of the active reconfigurable circuit cell and further connectable to any nodes of the other controlled source as input nodes are connected to output nodes as shown in FIG. 8. In FIG. 8 the diagonal connections of the passive circuit and the connections between the individual nodes j, k, m, n, j′, k′, m′, n′ of the controlled sources Gm, Rm to the nodes A₁, A₂, A₃, A₄ of the passive network of the reconfigurable circuit cell are not shown for simplicity. In FIG. 8, the outputs m, n of the transconductance amplifier Gm are connectable to the inputs j′, k′ of the transimpedance amplifier Rm and reciprocally the outputs m′, n′ of the Rm amplifier are connectable to the inputs j, k of the Gm amplifier. Accordingly, the reconfigurable circuit cell can be represented by a connectable planar graph. It is to be noted that in a specific real-life design, one type controlled source may suffice as e.g. a transistor. It is further noted that the design process may be carried out on a virtual machine and then down-loaded into a configurable area.

In FIG. 9 a universal type of reconfigurable circuit cell comprising four nodes B₁, B₂, B₃, B₄ both active and passive circuit elements is shown. As can be seen in FIG. 9 it has a simple topology for the sake of simple, either physical or virtual implementations. As a 4 node complete graph it is further representable by a planar, connectable graph so as to be physically realizable, the respective graph being complete so as to implement all possible connections between nodes.

Furthermore, the universal reconfigurable circuit cell of FIG. 9 includes both an active structure (dashed connections) and a passive structure, wherein the passive structure includes simple links. The nodes 1a, 2a, 3a and 4a belong to the active cell and the rest of the nodes belongs to the passive cell. Recall that the passive cells may comprise only wires and therefore using this concept any CMOS circuit may be designed. Recall that almost all CMOS digital circuits comprise active cells connected in different ways, while almost all CMOS linear circuits comprise active cells and connections between their respective nodes. The reconfigurable circuit cell of FIG. 9 may again be used as either a node or a link in an electrical circuit arrangement.

The main advantage of the concept of a general reconfigurable circuit cell containing both active and passive parts is that separate sets of data (“genomes”) may be used to configure any part of the cell i.e. the passive part and the active part. These separate sets of data may be referred to as configuration data sets. Moreover, the set of data of the universal reconfigurable circuit cell may, by way of example, be suitably divided into several parts as:

A first subset of data may be used to control the connectivity between the nodes of the passive part of the cell and the nodes of the active part of the cell; additionally, the bits allocated to passive cell may be grouped together, and the bits allocated to the active cell could be grouped together in a different group;

A second subset of data (“enable bit”) may additionally be used to indicate whether the cell is used or bypassed in a circuit implementation.

A third subset of data (“type bits”) may be used to indicate whether the cell is used purely as an active cell, i.e. without passive components, to indicate whether the cell is used purely as a passive cell, i.e. either comprising only admittances or simple connections, or finally to indicate that the cell is used universally i.e. comprising an active cell and a passive cell.

Pointers, as a fourth subset of data, may additionally be used to indicate the type and the values of the passive circuit elements, to show the type of active circuit element (e.g. a controlled source) used, and to indicate its model in a specific implementation. The pointers should address a database comprising the above-mentioned features.

As a particular device, a Micro-Electro-Mechanical System (MEMS) having in general a quadripolar representation and therefore being representable as a universal reconfigurable circuit cell as described above may be considered.

It is to be noted that using well-known equivalences between electrical devices and circuits, and mechanical, and pneumatically, hydraulically systems, and economical systems these systems may be also modeled using the above-mentioned process. Moreover, the reconfigurable circuit cells may be thought of either as links or as nodes, and that ultimately they may comprise any type of active circuit element, including transistors.

As a result, any circuit arrangement comprises nodes, links, passive devices, and active devices as transistors. Hence, a circuit implementable with lumped passive bi-terminal circuit elements and any type of controlled source, i.e. a specific active circuit element, may be implemented by using only the universal reconfigurable circuit cell shown in FIG. 9.

The concept of the present invention, namely to set up a complex electrical circuit arrangement by using a plurality of reconfigurable circuit cells, has a strong analogy in biology. A main property of any biological stem cell is that it can adjust to any type of cells connected to it. In fact it may be assumed that the environment “decides” what type of cell is used.

Hence, a main feature in designing circuits using reconfigurable circuit cells or stem cells is that a first reconfigurable circuit cell will set the type bits that reconfigure the next cell. As explained above, the type bits may determine whether the circuit cell is used as a passive cell, as an active cell, or as a full universal cell. As a starting point, it may be considered that the circuit cell is similar to those cells shown in FIG. 5, i.e. a circuit cell shown in FIG. 1b. Practically, this cell may be implemented in three alternatives, which may be further generalized for any type of circuit arrangement comprising such cells.

1. It is assumed that there is only one switch between each node M1, . . . , M4 in the circuit arrangement of FIG. 5 and predefined nodes of the reconfigurable circuit cell, say nodes 1 and 2. The predefined node 1 may be called the input node and the predefined node 2 the output node.
2. In a second alternative, some nodes of the cells coincide with the nodes of the circuit arrangement. This alternative has the advantage that it reduces the number of switches as it is shown in FIG. 5.
3. Each node of the circuit is connectable to any node of the reconfigurable circuit cell. In this configuration, each node will have 12 switches that allow connectivity.

The second alternative is the most economical one because it uses the smallest number of switches, while the third one is the most complex, but it permits the building of all possible configurations of the circuit arrangement.

A similar approach may be used when discussing the active part of the cell. Accordingly the type of active cell, which is used, may be prescribed as for example a MOS transistor and even more it may be considered as already connected to certain nodes. This would be the simplest configuration of the active cell, having the disadvantage that not all the connectivity possibilities between the active cell and the active cell may be implemented. It should be observed that when several connections are already made then there is no possibility to reallocate them to different nodes and therefore the reconfigurability is reduced. In particular, a circuit having only fixed connections is not at all reconfigurable. Alternatively, the active cell could be as complex as shown in FIG. 8, being able to implement any control source connections to any node of the passive circuit. This is the most complex configuration possible.

It is known in the art that circuit arrangements may basically be classified in analog and digital circuit arrangements. If the implementations are to be made in CMOS technology a possible implementation of the circuit shown in FIG. 5 should consider that the passive cells include only conductors and the active cells are MOS transistors. Furthermore, in a circuit arrangement shown in FIG. 5 the hyper nodes may be pure active cells and the hyper links may be pure passive cells.

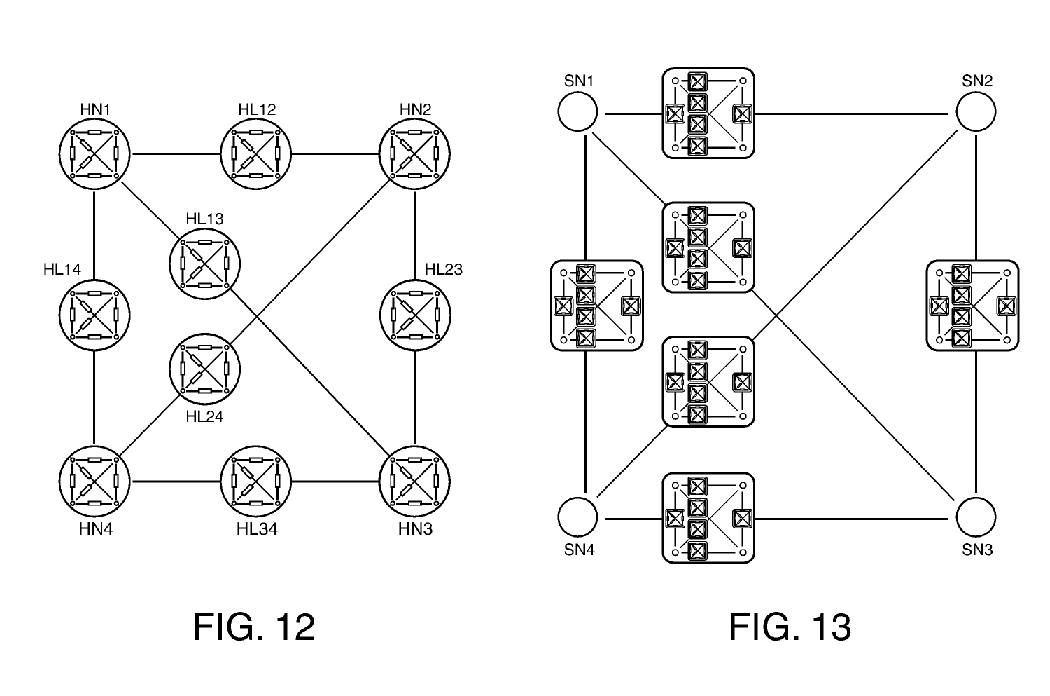

However, an alternative circuit in which the passive cells are the hyper nodes and the active cells are the hyper links is equally possible, as it is shown in FIGS. 7 and 12 in which it may be considered that the cells are complex circuit cells comprising both active and passive part.

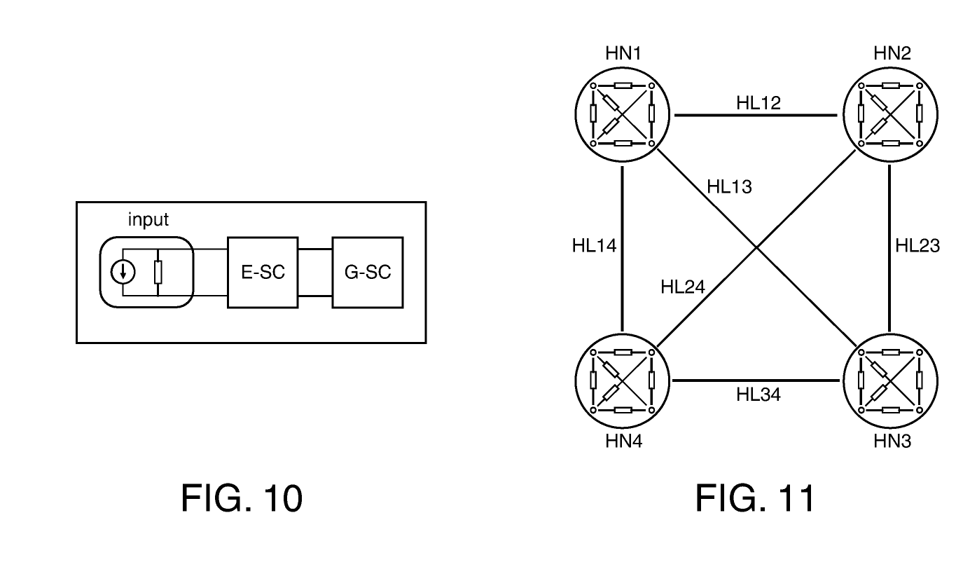

In analog design, any circuit may be partitioned in two parts, e.g. a frequency equalization part or simply equalization part and a gain part. The circuit can look as shown in FIG. 10.

In FIG. 10, a circuit arrangement comprising an equalizer subcircuit (E-SC) coupled to a gain subcircuit (G-SC), is presented. According to the present invention, either the E-SC or the G-SC or both are reconfigurable. The E-SC receives a signal from the Input circuit comprising a current source coupled in parallel to an admittance. By using Thevenin's theorem, the input circuit can be transformed into a voltage source coupled in series to an impedance. It is to be noted that any circuit can be depicted in this way, either directly or by using the generalized Norton theorem.

The E-SC should fulfill the following equation:

T_{E-SC}*Tᵢₙₚᵤₜ=K (16)

In equation (16) T_{E-SC} is the transfer function of the equalization stem cell and is generally a complex function having poles and zeroes. Normally it is implemented as a passive reconfigurable circuit cell. Tᵢₙₚᵤₜ is the transfer function characterizing the input source. Ideally, the poles of one function are the zeroes of the other and reciprocally. As a consequence, the product of these functions should be constant as indicated in equation (16) by the constant K. Practically, relation (16) should be fulfilled over a given frequency range and should be a design criterion. Two possible designs are possible:

1. The transfer function of the input device is partitioned in simpler functions, each function being implemented as a passive circuit cell, the cells being further connected in cascade. If this approach is used, a database comprising different configurations can be filled in and the design process reduces to a search—choose—fit algorithm, i.e. search into the database, choose the appropriate circuit topology and, provide the appropriate devices such that equation (16) is fulfilled.
2. In a second approach, the whole function is synthesized starting with a circuit shown in FIG. 1b and continuing with the circuit shown in FIG. 5 until the equation (16) is fulfilled.

The equalization phase is followed by a gain equalization phase in which equation (17) should be fulfilled.

K_{G-SC}*K=G (17)

In equation (17), K_{G-SC} is the gain of the G-SC, K is given by the equation (16), and G is the overall gain that should be obtained by the circuit arrangement in the required frequency range. Normally speaking, G>1 and as a consequence, the gain reconfigurable circuit cell circuit is an active one or a combination of an active and a passive one. Hence, the design process of the G-SC circuit could be similar to the second algorithm outlined above for the E-SC circuit.

The principles for designing electrical circuit arrangements outlined in this patent application can be generalized as shown in FIGS. 11, 12 and 13.

FIG. 11 represents a circuit arrangement comprising hyper nodes HN₁, HN₂, HN₃, HN₄, each including a generalized reconfigurable circuit cell, the hyper nodes being connected via hyper links HLᵢⱼ, i, j=1, . . . , 4, i≠j. Each hyper link may be a simple connectable link, or a vector of links.

The circuit shown in FIG. 11 may be further generalized as shown in FIG. 13 in which both each hyper node HN₁, HN₂, HN₃, HN₄ and each hyper link HLᵢⱼ are reconfigurable circuit cells.

The circuit may be further increased as shown in FIG. 13. FIG. 13 looks very much like the circuit shown in FIG. 5. It comprises super nodes SN₁, SN₂, SN₃, SN₄. In the circuit arrangement of FIG. 13 the hyper links are implemented as the circuits shown in FIG. 11. The principle may further be pursued by designing the super nodes SN₁, SN₂, SN₃, SN₄ as circuit arrangements shown in FIG. 13 itself.

Hence, the process can be formulated as:

1. Generate the circuit of FIG. 1b;
2. Generate the circuit of FIG. 5;
3. Generate the circuit of FIG. 11;
4. Generate the circuit of FIG. 12;
5. Generate the circuit of FIG. 13; and so on.
Another advantage of this approach is that reconfigurable circuit cells are used as links or hyper links, then in the event that the circuit becomes defective, a full cell is disposable to try to repair the circuit.

In the above approach a so-called bottom-up approach is used, i.e. synthesizing a relatively more complex circuit starting from a very simple one. This method follows the biological process resulting in generating more complex entities having a plurality of cells starting from one cell. However, technically speaking it is also possible to use a top-down approach, in which one may start from the circuit shown in FIG. 13, which is the most complicate one, and will finish with the definition of each and every cell.

The invention is defined by the independent claims. Dependent claims describe advantageous implementations.

1. Electrical circuit arrangement comprising:
a plurality of reconfigurable circuit cells, each reconfigurable circuit cell including:
a plurality of nodes,
a plurality of links connectable to the nodes,
at least one circuit element,
wherein the reconfigurable circuit cells are each configured to form either a node or a link of the electrical circuit arrangement.

2. Electrical circuit arrangement as claimed in claim 1, wherein in each reconfigurable circuit cell each node is connectable to any other node of the cell via one of a link and the at least one circuit element.

3. Electrical circuit arrangement as claimed in claim 1, wherein each reconfigurable circuit cell is representable by a planar graph.

4. Electrical circuit arrangement as claimed in claim 1, wherein the at least one circuit element is a passive circuit element.

5. Electrical circuit arrangement as claimed in claim 4, wherein said passive circuit element is a passive bi-terminal device.

6. Electrical circuit arrangement as claimed in claim 4, wherein at least one reconfigurable circuit cell of said plurality of reconfigurable circuit cells is a passive cell having at least one passive circuit element.

7. Electrical circuit arrangement as claimed in claim 1, wherein the at least one circuit element is an active circuit element.

8. Electrical circuit arrangement as claimed in claim 7, wherein said active circuit element has at least three terminals.

9. Electrical circuit arrangement as claimed in claim 7, wherein at least one reconfigurable circuit cell of said plurality of reconfigurable circuit cells is an active cell having at least one active circuit element.

10. Electrical circuit arrangement as claimed in claim 6, wherein the electrical circuit arrangement has a first plurality of passive cells, said passive cells each forming a hyper link of the circuit arrangement and a second plurality of active cells each forming a hyper node of the electrical circuit arrangement.

11. Electrical circuit arrangement as claimed in claim 6, wherein the electrical circuit arrangement is a CMOS circuit having a first plurality of passive cells said passive cells, each having a passive circuit element in a form of a conductor and a second plurality of active cells each forming a MOS transistor.

12. Electrical circuit arrangement as claimed in claim 6, wherein the electrical circuit arrangement has a first plurality of passive cells, said passive cells each forming a hyper node of the circuit arrangement, and a second plurality of active cells each forming a hyper link of the electrical circuit arrangement.

13. Electrical circuit arrangement as claimed in claim 1, wherein the plurality of circuit cells form at least one equalizer subcircuit and at least one gain subcircuit, and wherein each equalizer subcircuit is coupled to a gain subcircuit.

14. Electrical circuit arrangement as claimed in claim 1, wherein each reconfigurable circuit cell is configured by a set of data.

15. Electrical circuit arrangement as claimed in claim 14, wherein said set of data comprises a first subset of data for controlling connectivity between the links and nodes of the reconfigurable circuit cell.

16. Electrical circuit arrangement as claimed in claim 14, wherein said set of data comprises a second subset of data for bypassing the cell.

17. Electrical circuit arrangement as claimed in claim 14,
wherein said set of data comprises a third subset of data for indicating a type of the at least one circuit element.

18. Electrical circuit arrangement as claimed in claim 14, wherein said set of data comprises a fourth subset of data for indicating a type and a value of the at least one circuit element.

19. Method for designing an electrical circuit arrangement, wherein a plurality of reconfigurable circuit cells is provided, each reconfigurable circuit cell having a plurality of nodes, a plurality of links connectable to the nodes and at least one circuit element, wherein each reconfigurable circuit cell is configured by a set of data, the method comprising the steps of:
successively setting up the circuit by successively connecting the reconfigurable circuit cells of said plurality of reconfigurable circuit cells,
wherein a first connected reconfigurable circuit cell determines the set of data of the next reconfigurable circuit cell to be connected.
